(19) United States
(12) Patent Application Publication
(10) Pub. No.: US 2010/0103619 A1
(43) Pub. Date: Apr. 29, 2010

(54) Interchangeable Heat Exchanger for a Circuit Board

(76) Inventors: Gamal Refai-Ahmed, Markham (CA); Geoff Lyon, SW Calgary (CA); Khalid Sheltami, Richmond Hill (CA)

Correspondence Address: TIMOTHY M HONEYCUTT ATTORNEY AT LAW, P O BOX 1577, CYPRESS, TX, 77410, US

(21) Appl. No.: 12/582,896

(22) Filed: Oct. 21, 2009

Related U.S. Application Data
(60) Provisional application No. 61/107,795, filed on Oct. 23, 2008.

(51) Int. Cl. H05K 7/20; B23P 11/00; H01L 23/367; H01L 23/473

(52) U.S. Cl. 361/701; 29/428; 165/104.31; 165/104.33; 165/121; 165/185

(57) ABSTRACT

Various circuit board fluid cooling systems and methods of using the same are disclosed. In one aspect, a method of manufacturing is provided that includes coupling a first member to a circuit board where the first member has a first opening with a first internal footprint. A heat exchanger is removably coupled to the first member to transfer heat from at least one component of the circuit board. The heat exchanger has an external footprint adapted so that at least a portion of the heat exchanger fits in the first opening. A plate is coupled to the circuit board to transfer heat from at least one component of the circuit board. A fluid supply line and a fluid return line are coupled to the heat exchanger such that one of the fluid supply line and the fluid return line is thermal contact with the plate to transfer heat therefrom.

This application claims benefit under 35 U.S.C. 119(e) of prior provisional application Ser. No. 61/107,795, filed Oct. 23, 2008.

### BACKGROUND OF THE INVENTION

1. Field of the Invention

This invention relates generally to heat transfer devices, and more particularly to apparatus and methods for cooling circuit boards.

2. Description of the Related Art

Heat is an adversary of most electronic devices. Integrated circuits, such as various types of processors, can be particularly susceptible to heat-related performance problems or device failure. Over the years, the problem of cooling integrated circuits has been tackled in a variety of ways. For conventional plastic or ceramic packaged integrated circuits, cooling fans, heat fins and even liquid cooling systems have been used, often with great success.

One conventional variant of a liquid cooling system for use on a circuit card consists of a pair of metal plates that are joined by metal coolant supply and return lines. The plates are designed to seat on various components of the circuit card, such as voltage regulator and memory chips, and be fastened to the circuit card with screws. A third plate is fitted with a heat exchanger that is connected to the coolant supply and return lines by way of clamped flex hoses. The third plate is seated on the major heat generator of the circuit card, which is typically the main card processor, and secured by screws. The coolant supply and return lines are designed to connect to a coolant pumping system that includes a pump and cooling fan. The combination of the heat exchanger and the third plate is of integral construction and generally customized for a given generation of circuit card. Of all the components in this conventional system, the heat exchanger is the most complex in terms of design, manufacturing and cost.

A difficulty arises with the conventional liquid cooling system if an end user chooses or is forced to switch to another generation of circuit card. The chances are great that the next generation circuit card will have a different layout of components, such as chips, passive devices and I/O ports. Thus, the conventional plates cannot be used on the new cards. Indeed, the most expensive part to remake, the heat exchanger, will have to be redesigned and requalified to fit the new cards.

The present invention is directed to overcoming or reducing the effects of one or more of the foregoing disadvantages.

### SUMMARY OF THE INVENTION

In accordance with one aspect of the present invention, a method of manufacturing is provided that includes coupling a first member to a circuit board where the first member has a first opening with a first internal footprint. A heat exchanger is removably coupled to the first member to transfer heat from at least one component of the circuit board. The heat exchanger has an external footprint adapted so that at least a portion of the heat exchanger fits in the first opening. A plate is coupled to the circuit board to transfer heat from at least one component of the circuit board. A fluid supply line and a fluid return line are coupled to the heat exchanger such that one of the fluid supply line and the fluid return line is thermal contact with the plate to transfer heat therefrom.

In accordance with another aspect of the present invention, a method of manufacturing is provided that includes forming a first member that is adapted to couple to a circuit board and has a first opening with a first internal footprint. A heat exchanger is formed that is adapted to be removably coupled to the first member and to transfer heat from at least one component of the circuit board. The heat exchanger has an external footprint adapted so that at least a portion of the heat exchanger fits in the first opening. A plate is formed that is adapted to couple to the circuit board and be in thermal contact with at least one component of the circuit board and with a fluid line coupled to the heat exchanger.

In accordance with another aspect of the present invention, an apparatus is provided that includes a first member adapted to couple to a circuit board and having a first opening with a first internal footprint. A heat exchanger is removably coupled to the first member and adapted to transfer heat from at least one component of the circuit board. The heat exchanger has an external footprint adapted so that at least a portion of the heat exchanger fits in the first opening. A fluid supply line and a fluid return line are coupled to the heat exchanger. A plate is adapted to couple to the circuit board. One of the fluid supply line and the fluid return line is in thermal contact with the plate to transfer heat therefrom.

In accordance with another aspect of the present invention, an apparatus is provided that includes a circuit board and a first member coupled to the circuit board that has a first opening with a first internal footprint. A heat exchanger is removably coupled to the first member and adapted to transfer heat from at least one component of the circuit board. The heat exchanger has an external footprint adapted so that at least a portion of the heat exchanger fits in the first opening. A fluid supply line and a fluid return line are coupled to the heat exchanger. A plate is coupled to the circuit board. One of the fluid supply line and the fluid return line is in thermal contact with the plate to transfer heat therefrom.

### BRIEF DESCRIPTION OF THE DRAWINGS

The foregoing and other advantages of the invention will become apparent upon reading the following detailed description and upon reference to the drawings in which:

FIG. 1 is a partially exploded pictorial view of an exemplary conventional liquid cooling system for a conventional circuit card;

FIG. 2 is a schematic view of a conventional computer system incorporating the conventional liquid cooling system;

FIG. 3 is a partially exploded pictorial view of an exemplary embodiment of a fluid cooling system for a circuit board;

FIG. 4 is an overhead view of a portion of the exemplary fluid cooling system depicted in FIG. 3;

FIG. 5 is a sectional view of FIG. 4 taken at section 5-5;

FIG. 6 is a sectional view of FIG. 3 taken at section 6-6;

FIG. 7 is an overhead view of two exemplary members for holding an exemplary heat exchanger;

FIG. 8 is an overhead view of an alternate exemplary embodiment of a fluid cooling system for a circuit board;

FIG. 9 is a sectional view of an alternate exemplary embodiment of a heat exchanger;

FIG. 10 is a partially exploded pictorial view of an alternate exemplary embodiment of a fluid cooling system for a circuit board employing an alternate mounting scheme; and

FIG. 11 is a sectional view of FIG. 10 taken at section 11-11.

### DETAILED DESCRIPTION OF SPECIFIC EMBODIMENTS

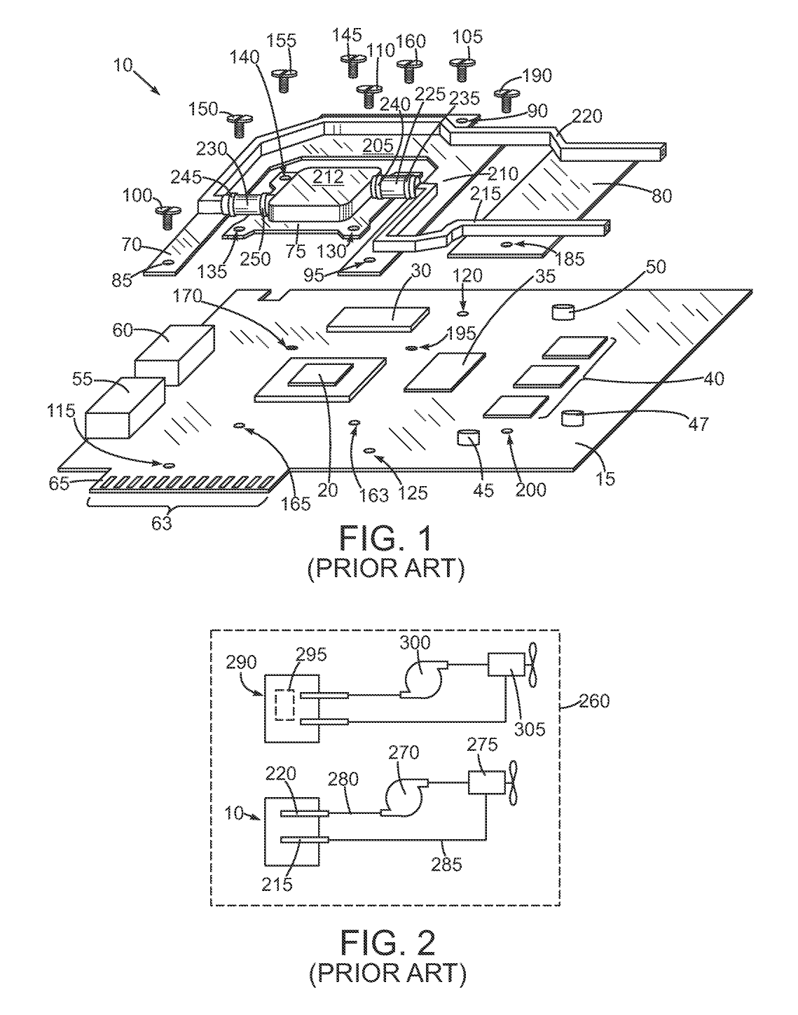

In the drawings described below, reference numerals are generally repeated where identical elements appear in more than one figure. Turning now to the drawings, and in particular to FIG. 1, therein is shown a partially exploded pictorial view of an exemplary conventional liquid cooling system 10 for a conventional circuit card 15. The circuit card 15 includes a variety of electronic elements, such as a graphics processing unit (GPU) 25, voltage regulator components 30 and 35 and memory devices 40. A few passive devices, such as the capacitors 45, 47 and 50, are depicted as well as output ports 55 and 60. The output ports 55 and 60 are designed to interface with cabling to other devices. The card 15 also includes a plurality of I/O conductors 63 that are fabricated on a projection 65. The projection 65 is designed to be inserted into a slot on another printed circuit board (not shown).

The cooling system 10 is designed to function as a heat exchanger for the circuit card 15 and is, accordingly, provided with several structures that are configured to target the heat dissipation of various structures on the circuit card 15. In this regard, the system 10 includes plates 70, 75 and 80 that are designed to be fastened to the card 15 by way of several screws. The plate 70 includes plural bores 85, 90 and 95 to receive respective screws 100, 105 and 110 that thread into corresponding bores 115, 120 and 125 in the card 15. The plate 75 similarly includes bores 130, 135 and 140 (and a fourth that is not visible in FIG. 1) that are designed to receive respective screws 145, 150, 155 and 160 that are, in turn, threaded to corresponding bores 163, 165, 170 and 175 in the card 15. Finally, the plate 80 includes a bore 185 and a screw 190 to thread into a bore 200 in the card 15. Another screw and bore (not shown) may be used to connect the other end of the plate 80 if desired. The plate 70 is provided with enlarged contact areas 205 and 210 that are designed to seat on and act as heat sinks for the voltage regulator components 30 and 35, respectively. The plate 80 is designed to seat on and serve as a heat sink for the memory components 40. The plate 75 is designed to seat on and act as a heat sink for the GPU 25. The plates 70, 75 and 80 are typically composed of aluminum or a nickel jacketed copper configuration.

The system 10 is designed to connect to an active coolant circulation system to remove heat from the plates 70, 75 and 80. In this regard, a pair of heat pipes 215 and 220 are connected as follows. The heat pipe 215 is attached to the plate 80 and the portion 210 of the plate 70, and leads into and is in fluid communication with the cooling chamber 212 on the plate 75. The heat pipe 220 is also attached to the plates 70 and 80 and is in fluid communication with the chamber 212. The pipes 215 and 220 serve as supply and/or return lines for a forced convection heat transfer system to be described in more detail below. The heat pipe 215 is connected to the chamber 212 by way of a flex hose 225. The heat pipe 220 is connected to the chamber 212 by way of a corresponding flex hose 230. The heat pipes 215 and 220 are composed of copper and each consists of a conduit through which a coolant may flow. The flex hose 225 is secured to the heat pipe 215 by way of a clamping strap 235 and to the chamber 212 by way of another clamping strap 240. The flex coupling 230 is similarly connected to the heat pipe 220 and the chamber 212 by way of respective clamping straps 245 and 250.

Attention is now turned to FIG. 2, which is a schematic view of a computing device 260, such as a computer or other computing device, that is supplied with an active coolant liquid cooling system 265 that includes the cooling system 10 connected to a fluid pump 270 and a cooling fan 275. A line 280 connects the pump 270 to the heat pipe 220 and a line 285 connects the heat pipe 215 to the cooling fan 275. The cooling fan 275 serves as a heat exchanger. The system 265 further includes another cooling sub-system 290 which is designed to provide active liquid cooling to a central processing unit 295 shown in phantom. Like the system 10, the cooling sub-system 290 is connected up to a fluid pump 300 and a cooling fan 305.

As noted in the Background section hereof, a conventional cooling sub-system, such as the sub-system 10 depicted in FIGS. 1 and 2, is only partially customizable in order to account for differences in the size and configuration of the GPU 25 and the card 15 and other components thereof. In this regard, a completely different chamber and plate combination, such as the combination 212 and 75 depicted in FIG. 1, may be removed from the system 10 by undoing the flex hoses 225 and 230 and swapped out for another combination of a plate and chamber. However, the plate and chamber for a different configuration of the card 15 and/or GPU 25 will require the complex manufacturer of a cooling chamber that is physically attached to a specifically shaped and designed plate 75.

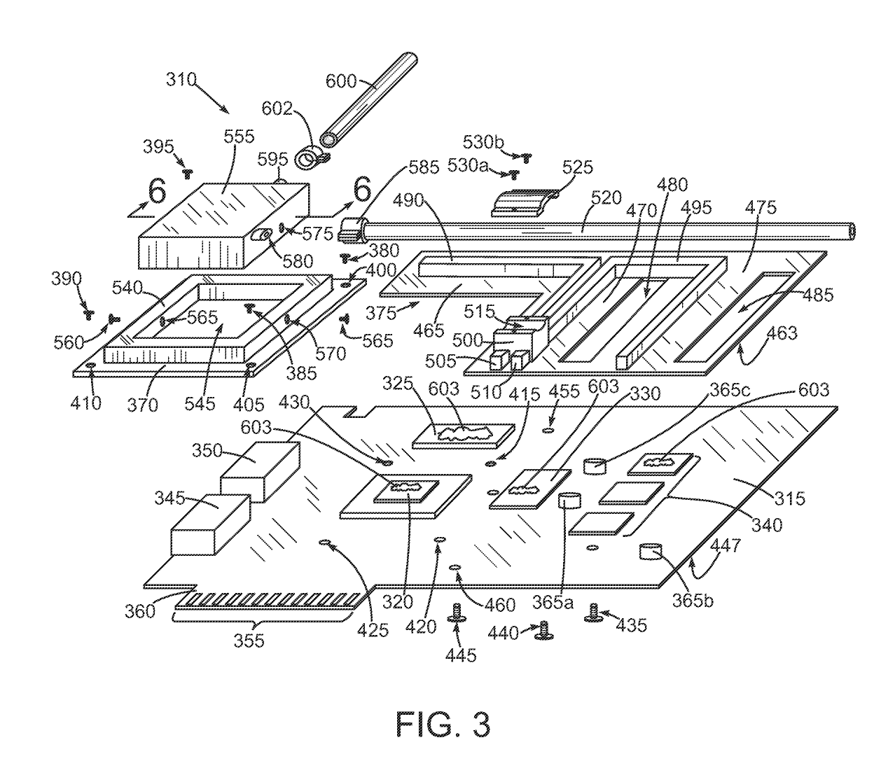

An exemplary embodiment of an improved cooling system 310 may be understood by referring now to FIG. 3, which is a partially exploded pictorial view showing the system 310 exploded from an exemplary circuit board or card 315. The circuit board 315 includes a semiconductor chip 320, voltage regulator components 325 and 330 and memory devices 340. The semiconductor chip 320 may be a microprocessor, a graphics processor, a combined microprocessor/graphics processor, an application specific integrated circuit, an optical device such as a pump laser, or virtually any other device that may benefit from thermal management. Input/output with external peripherals may be provided by way of input/output ports 345 and 350. The circuit card 315 may interface with another circuit board or electronic device (not shown) by way of a conductor array 355 that is fabricated on a blade or projection 360. The board 315 will typically include one or more passive devices, three of which are shown and labeled 365a, 365b and 365c. The cooling system 310 includes a member 370 and a plate 375 that are designed to be coupled to the board 315. The member 370 may be connected to the board 315 by way of screws 380, 385, 390 and 395 that project through respective bores 400, 405, 410 (and a fourth that is not visible) in the member 370 and threadedly engage corresponding bores 415, 420, 425 and 430 in the board 315. The plate 375 may be connected to the board 315 by way of screws 435, 440 and 445 that project up from the back side 447 of the board 315 and through corresponding bores 450, 455 and 460 in the card. The screws 435, 440 and 445 engage bores in the back side 463 of the plate 375 that are not visible. The plate 375 is provided with three enlarged areas 465, 470 and 475 that are designed to seat on the memory devices 340 and the voltage regulator components 325 and 330, respectively. Cut-outs 480 and 485 may be provided in the plate 375 in order to reduce the weight thereof and to accommodate upwardly projecting devices that may be present on the board 315.

A pair of heat sinks 490 and 495 are positioned on the plate 375. The heat sink 490, a pipe in this embodiment, is designed to provide a thermal interface, principally for the enlarged area 465. The heat sink 495, also a pipe in this embodiment, is designed to provide a thermal interface for a portion of the enlarged area 470 and the enlarged area 475. A block 500 is seated over the respective ends 505 and 510 of the heat sinks 490 and 495. The block 500 includes a channel 515 that is sized to enable a fluid supply/return tube 520 to be seated therein. The supply/return tube 520 may be held in the channel 515 by a strap 525 that is secured to the block 500 by one or more screws 530a and 530b. When the supply/return line 520 is secured to the block 500, the heat sinks 490 and 495 and the supply/return line 520 are all thermally linked. The significance of this feature will be described in more detail below. The heat sinks 490 and 495 may or may not contain fluid.

The plate member is provided with a ring 540 that has an internal opening 545 with an internal footprint or perimeter that is designed to closely match the external footprint of a heat exchanger 555, which is shown exploded from the ring 540. However, when assembled, the heat exchanger 555 is dropped into the ring 540 and secured thereto, for example, by way of screws 560 and 565 that thread through respective bores 570 and 575 in the ring. The heat exchanger 555 has a corresponding thread bore 575 and one opposite that is not visible in FIG. 3 to receive the screws 560 and 565. The heat exchanger 555 is designed to transfer heat from the GPU 320 and possibly other components on the circuit board 315. In this regard, the heat exchanger 555 includes an inlet/outlet port 580 that is designed to connect to the end 585 of the supply/return line 520 by way of a clamp 585 or other fastening mechanism and an inlet/outlet port 590 that is designed to connect to another supply/return line 600. A clamp 602 or other fastening mechanism may be used to secure the supply/return line 600 to the port 595. The supply/return lines 520 and 600 may connect to a cooling fluid circulation system, such as the system depicted in FIG. 2 that includes the pump 270, the fan 275 and the lines 280 and 285, or virtually any other fluid cooling system. As described elsewhere herein, a variety of fluids, including two-phase fluids, may be used. Accordingly, as used herein, the term “pump” should be understood to include not only a pump, but also a compressor or other fluid transport device. The supply/return line 520 may be composed of copper, aluminum, nickel, stainless steel, combinations of these of the like. The supply/return line 600 may be composed of polymeric materials such as rubbers, copper, aluminum, nickel, stainless steel, combinations of these of the like.

To enhance thermal conductivity, a heat transfer material 603 may be applied to the GPU 320, the voltage regulator components 325 and 330 and the memory devices 340. The heat transfer material 603 may be a thermal grease, paste or a thermal potting. Exemplary materials include G974, T725, Therm-A-gap 575 by Chormerics or the like.

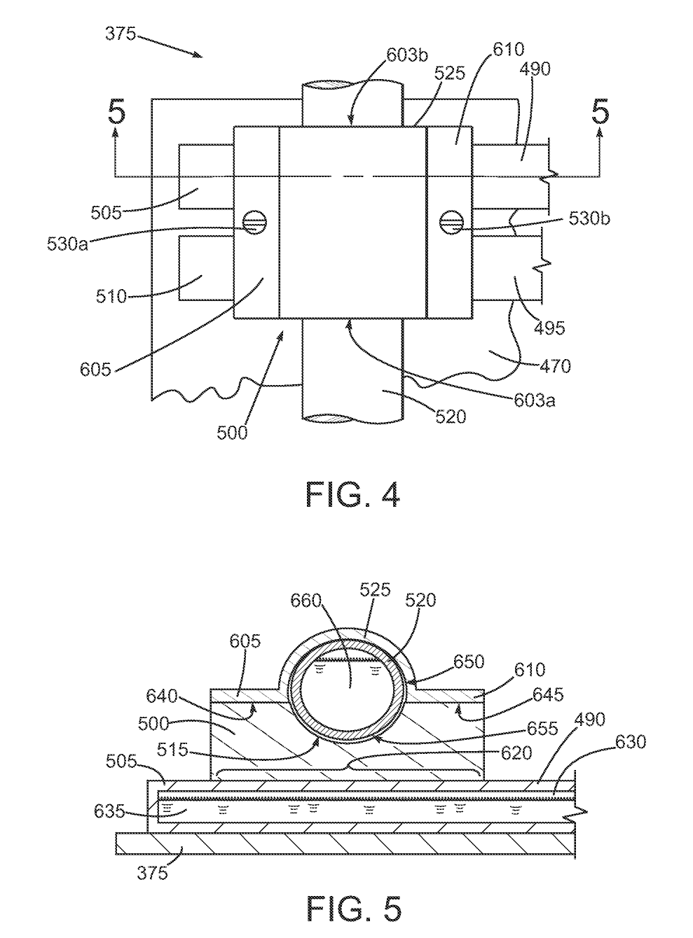

Additional details of the block 500 depicted in FIG. 3 may be understood by referring now to FIG. 4, which is an overhead view of the block 500 and a portion of the enlarged area 470 of the plate 375 as well as the ends 505 and 510 of the heat sinks 490 and 495. Note that only a small portion of the supply/return line 520 is depicted projecting from opposite ends 603a and 603b of the block 500. The strap 525 includes opposing flats 605 and 610 through which the screws 530a and 530b project. Attention is now turned to FIG. 5, which is a sectional view of FIG. 4 taken at section 5-5. Note that the location of section 5-5 is such that the heat sink 490 and the end 505 thereof are shown in section but the screws and the remainder of the structures depicted in FIG. 4 are not visible. The block 500 is advantageously provided with a through bore 620 that accommodates the heat sink 490 and provides a relatively snug interface so that the block 500 and the heat sink 490 present a low thermal resistance heat transfer pathway. As noted briefly above, the heat sink 490 includes an internal chamber 630 that is designed to hold a volume of a coolant 635 that may be water, glycol, or some other type of fluid suitable for coolant. Optionally, the coolant 635 may be a refrigerated fluid that is liquid phase, gaseous phase or both.

The block 500 is provided with respective flats 640 and 645 that are designed to receive the flats 605 and 610 of the strap 525. The strap 525 includes a channel 650 that is configured like a half-cylinder to accommodate the supply/return line 520 that is seated in the channel 515 of the block 500. The space 655 between the channel 515 and the outer surface of the supply/return line 520 may be filled with a thermal grease or other heat transfer material. Optionally, the space 655 may be filled with thermally conductive oil. Such an oil configuration will require seals at respective ends 603a and 603b (see FIG. 4) of the block 500 that are not shown. With the supply/return line 520 in place and conveying pumped coolant 660, heat can be transferred away from the plate 375 via the pathway that includes both the plate 375 itself, and the heat pipe 490 shown in FIGS. 4 and 5 and heat sink 495 shown in FIG. 3 through the block 500 and via the supply/return line 520. More heat may be transferred from the block 500 if the supply/return line 520 is plumbed as a supply line. However, the supply/return line 600 could be configured as a supply line and the line 520 as a return if desired.

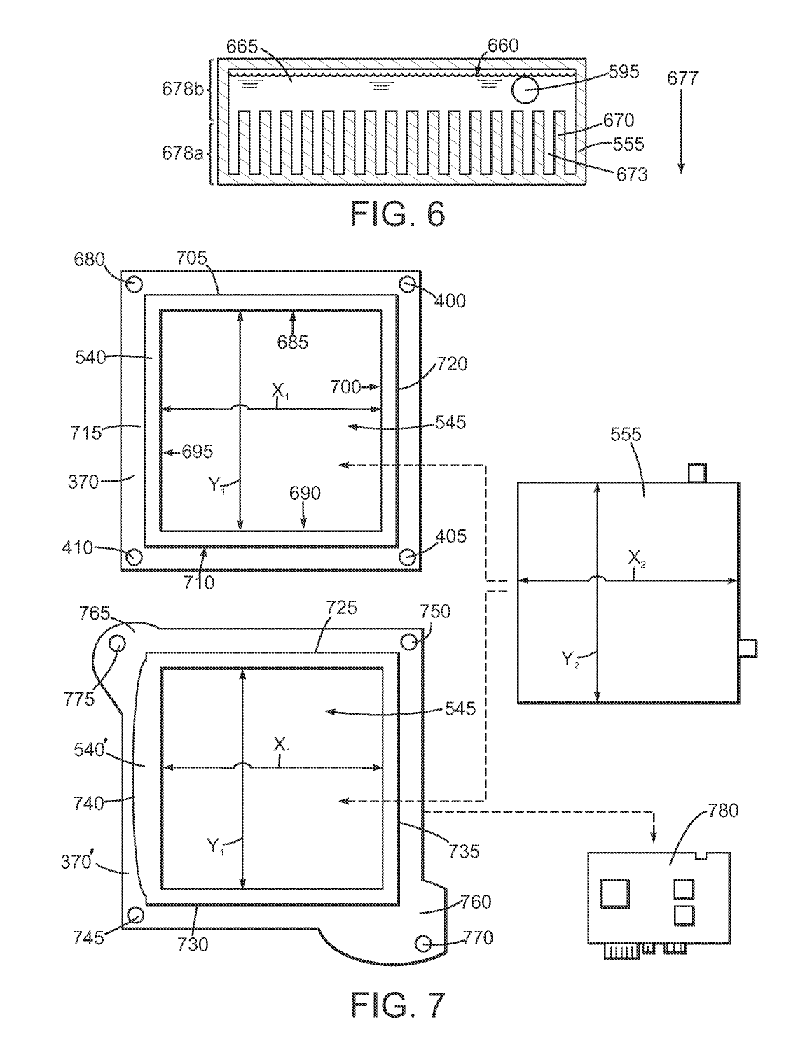

Additional details of the heat exchanger 555 depicted in FIG. 3 may be understood by referring now to FIG. 6, which is a sectional view of FIG. 3 taken at section 6-6. Note that the location of section 6-6 is such that the inlet/outlet port 580 of the heat exchanger 555 depicted in FIG. 3 is not visible. However, the inlet/outlet port 595 is visible. In this illustrative embodiment, the heat exchanger 555 includes an internal space 665 that is designed to accommodate the coolant 660 as it is circulated. To enhance the heat transfer characteristics of the heat exchanger 555, a plurality of micro-channels 673 defined by a plurality of spaced fins 675 may be provided within the internal space 665. The fins 675 may take on a great variety of different configurations. For example, as viewed in the direction of the arrow 677, the fins 675 may take on an elliptical footprint, a rectangular footprint, a serpentine footprint or virtually any other shape. The fins 675 may extend along the entire length of the heat exchanger 555, that is, in and out of the page, or consist of individual smaller segments as desired. It is not necessary for the entirety of the heat exchanger 555 to have a particular standard sized external footprint to fit various mounting members, such as the member 370 shown in FIG. 3. For example, only a lower portion 678a of the heat exchanger 555 may have the standard external footprint while the upper portion 678b need not. The upper portion 678b could be made larger than the lower portion 678a to hold a greater volume of fluid 660 and provide more heat transfer area.

The plates 370 and 375, the heat sinks 490 and 495, the block 500, the ring 540 and the heat exchanger 555 may be composed of a variety of thermally conducting materials, such as, for example, copper, aluminum, nickel, stainless steel, combinations of these or the like. Optionally, the member 370 and the ring 540 could be manufactured from polymeric materials. Well-known fabrication techniques may be used to form the various components, such as stamping, casting, plating, drawing, soldering, punching or the like.

As noted briefly above, the member 370 and ring 540 depicted in FIG. 3 allow for the easy customization of the cooling system 310 to accommodate different sizes of components that require cooling as well as the placement thereof, and different types of bores. The design flexibility may be understood by referring now to FIG. 7, which is an overhead view of the member 370 previously depicted in FIG. 3, the heat exchanger 555, and an alternate exemplary embodiment of another member 370′ also configured to hold the heat exchanger 555. Turning first to the member 370, the screw holes 400, 405, 410 and a fourth screw hole 680 that was not visible in FIG. 3 are shown. The internal opening 545 of the ring 540 is provided with a preselected size and shape or footprint. In this illustrative embodiment, the footprint of the internal opening 545 is rectangular and defined by two pairs of opposing sides 685 and 690 and 695 and 700 with a size represented by the dimensions X₁ and Y₁. Of course, if the internal opening 545 were other than rectangular, then other than a purely orthogonal set of measurements might be appropriate to define the footprint. For example, if the heat exchanger 555 had a circular or elliptical external footprint, then the internal opening 545 of the ring 540 might have a corresponding circular or elliptical footprint. In any case, the footprint of the internal opening 545 is designed to accommodate a standard external footprint for the heat exchanger 555. An example of a standard external footprint for the heat exchanger 555 is shown in FIG. 7. In this embodiment, the standard external footprint of the heat exchanger 555 is rectangular as defined by the external sides 705 and 710 and 715 and 720. The external footprint is very similar to the rectangular footprint of the internal opening 545 of the ring 540, but is defined by the dimensions X₂ and Y₂, which should be smaller than the dimensions X₁ and Y₁ so that the heat exchanger 555 can actually fit in the opening 545. Of course it would also be possible to make the external footprint of the heat exchanger 555 larger than that of the ring 540 and still make the appropriate insertion by expanding the ring 540 through heating, dropping in the heat exchanger 555 and allowing both to cool so that the ring 540 contracts snugly against the heat exchanger 555.

A standard sized heat exchanger 555 chamber may be used with multiple configurations of the circuit board 315 and/or processing unit 320 by changing the external footprint and configuration of the ring 540. Indeed, the external periphery, defined in this embodiment by the sides 705, 710, 715 and 720 and the member 370 may have virtually any shape so long as the internal footprint of the opening 545 is configured to accommodate a standard sized heat exchanger 555 shown in FIG. 3. The alternate exemplary member 370′ has an internal opening 545′ with an internal footprint configured with X₁ and Y₁ dimensions to also accommodate the standard external footprint heat exchanger 555. The internal footprint of the ring opening 545′ and the standard external footprint of the heat exchanger 555 need not have the same shape. However, a ring 540′ of the member 370′ has a different external footprint as defined by the two parallel, opposing sides 725 and 730, a relatively straight external side 735 and a curved side 740 positioned opposite the external side 735. In addition, the member 370′ has a different layout for screw holes. In this embodiment, the member 370′ has two screw holes 745 and 750 that are located in opposite corners and two enlarged projections 760 and 765 with respective screw holes 770 and 775 that are obviously located at different locations relative to the ring 540′ than the holes 400, 405, 410 and 680 of the member 370 depicted in FIG. 6. In this way, the member 370′ and the ring 540′ may be provided with an external configuration via the holes 745, 750, 770 and 775 to accommodate the same heat exchanger 555 but a different arrangement of a circuit board 780 (not shown to scale in relation to the member 370′) and screw connections thereto.

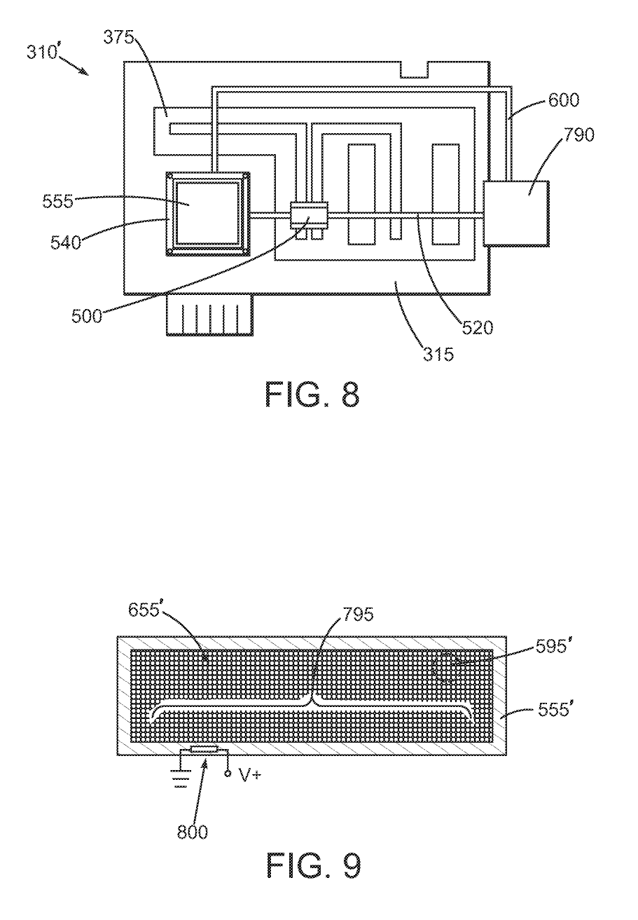

An alternate exemplary cooling system 310′ may be understood by referring now to FIG. 8, which is an overhead view that shows the cooling system 310′ used in conjunction with the circuit board 315 described elsewhere herein. In this illustrative embodiment, the interchangeable heat exchanger 555, ring 540, cooling plate 375, heat transfer block 500 and supply/return lines 520 and 600 may be used as generally described elsewhere herein. However, in lieu of a mechanical fluid mover, such as a pump or compressor, a capillary action heat exchanger 790 may be coupled to the supply/return lines 520 and 600 and used to circulate coolant to and from the heat exchanger 555. The capillary action heat exchanger 790 may be a micro-channel design, a sintered metal porous design or virtually any other design that utilizes capillary action to move fluids.

The skilled artisan will appreciate that the cooling systems 310 and 310′ depicted in FIGS. 3 and 8 may be used with a variety of circuit boards. Examples include circuit cards, motherboards, system boards or the like. Depending on the configuration of the circuit board, the heat exchanger 555 and member 370 or 370′ might be used separately from the plate 380. This might be desirable where another cooling system already exists for various components on a circuit board, and only the heat exchanger 555 and the member 370 or 370′ are to be added. The system 310 may be provided as a discrete system for use with a dedicated pump 270 and fan 275 as depicted in FIG. 2, or used as part of a larger liquid cooling system where manifolds or such are used to channel fluid to and from multiple locations. Furthermore, fastening methods other than screws may be used to secure the systems 310 and 310′ and components thereof to a circuit board, such as clips, rivets, clamps or even adhesives.

An alternate exemplary embodiment of a swappable heat exchanger may be understood by referring now to FIG. 9, which is a sectional view like FIG. 6. In this illustrative embodiment, a heat exchanger 555′ includes an internal chamber 655′ that is provided with a porous matrix or mesh structure 795 that is designed to provide both a large surface area for heat transfer as well as facilitate the movement of a fluid in the chamber 655′ by way of capillary action and/or natural convection in order to provide evaporative and condensive cooling action. Note that an inlet/outlet port 595′ is depicted in dashed since it is obscured by the porous matrix 795. If desired, the heat exchanger 555′ may be fitted with a plurality of channels, like the channels 673 depicted in FIG. 6, that may be used in combination with the porous matrix 795.

The heat exchanger 555′ may be provided with one or more thermoelectric cooling device 800 that may be fabricated as well-known Peltier effect devices. If a Peltier effect device is utilized, the device 800 may be connected to a voltage source in order to provide the requisite forward or reverse or bias as desired. The use of a thermoelectric cooling device 800 may be advantageous where it is anticipated that certain areas of the heat exchanger 555′ will be positioned over particularly high temperature areas or hot spots of an underlying electronic device that requires cooling. The thermoelectric cooling device 800 may be on or in the heat exchanger 555′. There may be any number of thermoelectric cooling devices 800 provided in the heat exchanger 555′. It should be noted that any of the embodiments of heat exchangers disclosed herein may be provided with one or more thermoelectric cooling devices 800.

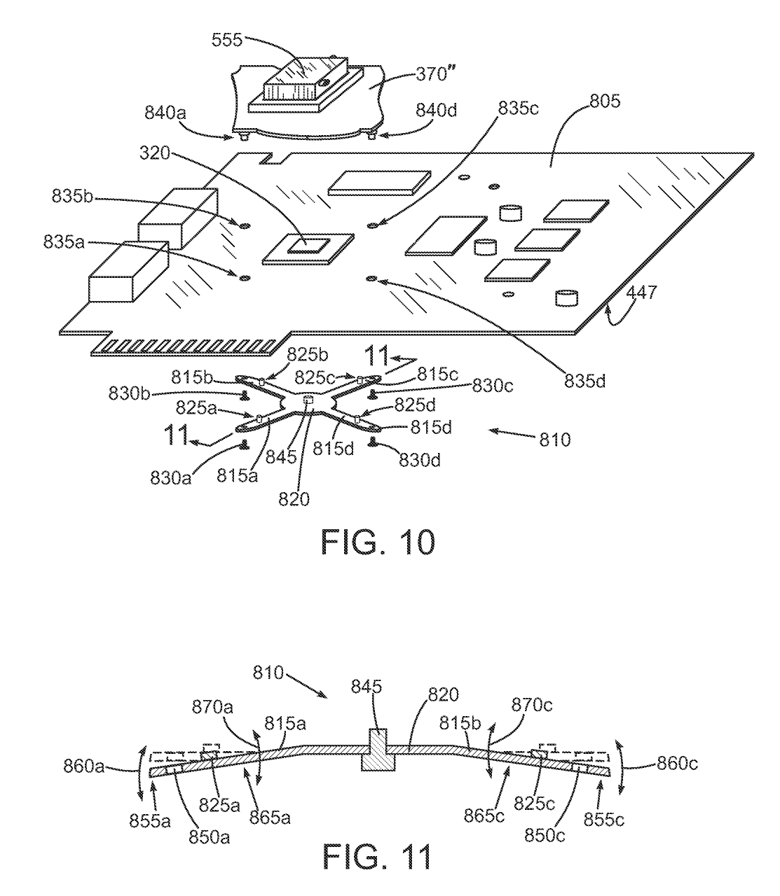

A spring-like member may be used to compliantly connect any of the disclosed embodiments of a swappable heat exchanger to a given circuit board. An alternate exemplary embodiment depicting this arrangement may be understood by referring now to FIG. 10. Here, a heat exchanger 555 mounted to a plate 370″ is shown exploded from a circuit board 805 that includes a semiconductor device 320. For simplicity of illustration, the remaining features of the circuit card 805 are omitted as well as the optional passive cooling system that includes the plate 375 depicted in FIG. 3 are omitted. Note the somewhat irregular shape of the plate 370″. This irregular shape is designed to again emphasize the concept that a plate of nearly infinite varieties of shapes may be used in conjunction with a standard external footprint heat exchanger 555. In this illustrative embodiment, a mounting member 810 may be used to secure the plate 370″ to the circuit board 805 from the back side 447 of the circuit board 805. The mounting member 810 may include a plurality of arms 815a, 815b, 815c and 815d and a central portion or hub 820 as desired. The arms 815a, 815b, 815c and 815d are provided with respective upwardly projecting members 825a, 825b, 825c and 825d. The members 825a, 825b, 825c and 825d are designed to bear against the underside 447 of the circuit board 805 when the mounting member 810 is secured to the plate 370″ by way of respective screws 830a, 830b, 830c and 830d. The screws 830a, 830b, 830c and 830d are designed to project through bores 835a, 835b, 835c and 835d in the card 447 and engage respective standoffs, two of which are shown and labeled 840a and 840b. The standoffs 840a and 840b may be provided with a vertical dimension that provides a desirable vertical position of the plate 370″ relative to the circuit card 805 and the semiconductor device 320. An alignment pin 845 may be provided on the central portion 820.

The alignment pin 845 is designed to project into an alignment bore (not visible) in the underside 447 of the circuit board 805.

Additional details of the mounting member 810 may be understood by referring now to FIG. 11, which is a sectional view of the mounting member 810 shown in FIG. 10 taken at section 11-11. Note that because of the location of section 11-11, the arm 815a and its respective member 825a and a screw bore 850a are visible along with the opposing arm 815c and its respective member 825c and bore 850c. The bores 850a and 850c are designed to receive the respective screws depicted in FIG. 10 to connect to the plate 370″ depicted in FIG. 10. As noted briefly above, when the mounting member 810 is secured to the plate 370″ depicted in FIG. 10, the arms 815a and 815c will be deformed from their natural states depicted in FIG. 11 to bent or biased states as depicted by the dashed portions in FIG. 11. At this stage, the projecting members 825a and 825c act as fulcrums to enable end portions 855a and 855c of the respective arms 815a and 815c to flex as indicated by the arrows 860a and 860c and interior portions 865a and 865c of the arms 815a and 815c to flex as indicated by the arrows 870a and 870c. As noted above, the alignment pin 845 may be positioned in a alignment bore (not visible) in the under side 447 of the circuit board 805. It should be understood that the mounting member 810 may be fabricated from a variety of materials, such as metals, plastics or the like, and may have two or more arms. The arms may be symmetrical or asymmetrical and may have a continuous shape or tapering shape as desired.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims. For example, multiple swappable heat exchangers could be used for a given circuit board.

What is claimed is:

1. A method of manufacturing, comprising:
coupling a first member to a circuit board, the first member having a first opening with a first internal footprint;
removably coupling a heat exchanger to the first member to transfer heat from at least one component of the circuit board, the heat exchanger having an external footprint adapted so that at least a portion of the heat exchanger fits in the first opening; and
coupling a fluid supply line and a fluid return line to the heat exchanger.

2. The method of claim 1, comprising coupling a plate to the circuit board to transfer heat from at least one component of the circuit board and wherein one of the fluid supply line and the fluid return line being in thermal contact with the plate to transfer heat therefrom.

3. The method of claim 1, comprising uncoupling the heat exchanger from the first member, removing the first member from the circuit board, coupling a second member to the circuit board, the second member having a second opening with the first internal footprint, and removably coupling the heat exchanger to the second member.

4. The method of claim 1, comprising uncoupling the heat exchanger from the first member, and removably coupling the heat exchanger to a second member adapted to coupled to another circuit board, the second member having a second opening with the first internal footprint.

5. The method of claim 1, comprising coupling a pump to the fluid supply line and the fluid return line.

6. The method of claim 5, comprising coupling a fan to the pump.

7. The method of claim 1, comprising coupling a computing device to the circuit board.

8. The method of claim 1, comprising coupling at least one thermoelectric cooling device to the heat exchanger.

9. A method of manufacturing, comprising:
forming a first member adapted to couple to a circuit board and having a first opening with a first internal footprint;
forming a heat exchanger adapted to be removably coupled to the first member and adapted to transfer heat from at least one component of the circuit board, the heat exchanger having an external footprint adapted so that at least a portion of the heat exchanger fits in the first opening; and
forming a plate adapted to couple to the circuit board, wherein the plate being adapted to be in thermal contact with at least one component of the circuit board and with a fluid line coupled to the heat exchanger.

10. The method of claim 9, comprising coupling a fluid supply line and a fluid return line coupled to the heat exchanger.

11. The method of claim 9, wherein the external footprint of the heat exchanger is adapted to fit in a second opening of a second member adapted to couple to another circuit board.

12. The method of claim 9, wherein the first internal footprint and the external footprint are rectangular.

13. The method of claim 9, wherein the first member comprises a ring.

14. The method of claim 9, comprising coupling a block to the plate, the block being in thermal contact with the fluid line.

15. The method of claim 14, comprising placing a thermally conductive medium between the block and fluid line.

16. The method of claim 9, comprising forming the plate with first and second heat sinks in thermal contact with the fluid line.

17. The method of claim 16, wherein the first and second heat sinks comprise heat pipes.

18. The method of claim 9, comprising coupling at least one thermoelectric cooling device to the heat exchanger.

19. An apparatus, comprising:
a first member adapted to couple to a circuit board and having a first opening with a first internal footprint;
a heat exchanger removably coupled to the first member and adapted to transfer heat from at least one component of the circuit board, the heat exchanger having an external footprint adapted so that at least a portion of the heat exchanger fits in the first opening;
a fluid supply line and a fluid return line coupled to the heat exchanger; and
wherein the external footprint of the heat exchanger is adapted to fit in a second opening of a second member adapted to couple to another circuit board.

20. The apparatus of claim 19, comprising a plate adapted to couple to the circuit board and wherein one of the fluid supply line and the fluid return line being in thermal contact with the plate to transfer heat therefrom.

21. The apparatus of claim 19, wherein the first internal footprint and the external footprint are rectangular.

22. The apparatus of claim 19, wherein the first member comprises a ring.

23. The apparatus of claim 19, comprising a block coupled to the plate, one of the fluid supply line and the fluid return line being in thermal contact with the block to transfer heat from the plate.

24. The apparatus of claim 23, wherein the block comprises a channel to receive the one of the fluid supply line and the fluid return line.

25. The apparatus of claim 23, comprising a thermally conductive medium between the block and the one of the fluid supply line and the fluid return line.

26. The apparatus of claim 19, wherein the plate comprises first and second heat sinks and a block coupled to the first and second heat sinks, one of the fluid supply line and the fluid return line being in thermal contact with the block to transfer heat from the plate.

27. The apparatus of claim 26, wherein the first and second heat sinks comprise heat pipes.

28. The apparatus of claim 19, comprising a pump coupled to the fluid supply line and the fluid return line.

29. The apparatus of claim 28, comprising a fan coupled to the pump.

30. The apparatus of claim 19, comprising a computing device coupled to the circuit board.

31. The apparatus of claim 19, comprising at least one thermoelectric cooling device coupled to the heat exchanger.

32. An apparatus, comprising:
a circuit board;
a first member coupled to the circuit board and having a first opening with a first internal footprint;
a heat exchanger removably coupled to the first member and adapted to transfer heat from at least one component of the circuit board, the heat exchanger having an external footprint adapted so that at least a portion of the heat exchanger fits in the first opening;
a fluid supply line and a fluid return line coupled to the heat exchanger;
a plate coupled to the circuit board; and
wherein one of the fluid supply line and the fluid return line being in thermal contact with the plate to transfer heat therefrom.

33. The apparatus of claim 32, wherein the external footprint of the heat exchanger is adapted to fit in a second opening of a second member adapted to couple to another circuit board.

34. The apparatus of claim 32, wherein the first internal footprint and the external footprint are rectangular.

35. The apparatus of claim 32, wherein the first member comprises a ring.

36. The apparatus of claim 32, comprising a block coupled to the plate, one of the fluid supply line and the fluid return line being in thermal contact with the block to transfer heat from the plate.

37. The apparatus of claim 36, wherein the block comprises a channel to receive the one of the fluid supply line and the fluid return line.

38. The apparatus of claim 36, comprising a thermally conductive medium between the block and the one of the fluid supply line and the fluid return line.

39. The apparatus of claim 32, wherein the plate comprises first and second heat sinks and a block coupled to the first and second heat sinks, one of the fluid supply line and the fluid return line being in thermal contact with the block to transfer heat from the plate.

40. The apparatus of claim 39, wherein the first and second heat sinks comprise heat pipes.

41. The apparatus of claim 32, comprising a pump coupled to the fluid supply line and the fluid return line.

42. The apparatus of claim 41, comprising a fan coupled to the pump.

43. The apparatus of claim 32, comprising a computing device coupled to the circuit board.
